(19) United States
(12) Patent Application Publication
(10) Pub. No.: US 2005/0127390 A1
(43) Pub. Date: Jun. 16, 2005

(54) LED package

(75) Inventors: Timothy Lin, Taipei (TW); Cheng-I Lin, Taipei (TW)

Correspondence Address: BRUCE H. TROXELL, SUITE 1404, 5205 LEESBURG PIKE, FALLS CHURCH, VA, 22041, US

(73) Assignees: Leashin Technologies Inc.; Apex Science-Engineering Corp.

(21) Appl. No.: 10/760,396

(22) Filed: Jan. 21, 2004

(30) Foreign Application Priority Data
Dec. 16, 2003 (TW) 92221974

(51) Int. Cl. H01L 33/00

(52) U.S. Cl. 257/100

(57) ABSTRACT

An improved LED package comprises a first stand, a second stand, an LED chip, an epoxy packaging object, wherein the first stand further comprises a concave bowl section, and a first pin is extended from the bottom of the first stand, and a second stand is disposed adjacent to the first stand and keeps a certain distance from the first stand. The LED chip is disposed in the bowl section at the top of the first stand, and the anode of the LED chip makes use of a conductive metal wire to electrically connect the second stand. The epoxy packaging object encapsulates the first stand, second stand, and LED chip inside and just leaves the first and second pins exposed. A plane perpendicular to the optical path of the light emitted by the LED chip is disposed on the top surface of the packaging object, and the top surface has more than one circular protrusion to achieve the objective of enhancing the brightness and uniformity of luminescence.

### 1. FIELD OF THE INVENTION

The present invention relates to an improved LED package, more particularly to a package having a top plane perpendicular to the optical path and at least one circular protrusion disposed thereon.

### 2. BACKGROUND OF THE INVENTION

In compliance with the fast pace and rapid change in the development of science and technology, all kinds of high-tech products are developed and introduced constantly, not only improving the quality of our life, but also bringing us lots of convenience. Taking the digital image processing for example, a digital array is generally used in the digital image processing for representing a physical image (as shown in FIG. 1). In this regard, a physical image is generally being divided into small regions called “picture elements” or “pixels” for short. The most common subdivision scheme is the rectangular sampling grid shown in the figure, where the image is divided into horizontal lines composed of adjacent pixels. The location of each pixel is assigned with a numeric value to reflect the brightness of the image at the corresponding point. The process of converting an image is called digitization, and one of the common form of digitizing an image is illustrated in FIG. 2. At each pixel location, the brightness of the image is sampled and quantified to obtain an integer representing the brightness or darkness of the image at that point. After the conversion of all the corresponding pixels is completed, the image is digitized and represented by a rectangular array of integers. Consequently, each pixel will have two attributes: integer location or address (line or row number and sample or column number) and an integer value called the gray level. This array of digital data is now a candidate for computer processing. By means of the aforementioned digital image processing technology, manufacturers can develop the following related peripheral products which are indispensable to our daily life, such as (1) industrial machine vision: including industrial inspection, industrial survey, automated production lone, postal service automation, computer-assisted surgical operation, microsurgical operation, and robots for various hazardous jobs and occasions; the image and vision technologies are applied in the industrial production automation, not only expediting the production speed and assuring the quality consistency, but also being capable of avoiding misjudgments due to people's weariness and unfocused attention; (2) human-machine interface: including facial recognition and intelligent agent capable of carrying out instructions according to the user's wishes and demands detected by the user's gesture (sign language), lip movement (lip reading), body movement (posture), and facial expression, etc; (3) vision guidance: including cruise missiles guidance, unmanned airplane aviations, automated motor vehicles, walking robots, and precision control and guide, which can avoid dangers brought by participating the activity and also improve the accuracy and speed; (4) virtual reality: including pilot training, medical operation simulation, scene model, battlefield environment representation, etc, which can help people to surpass our physiological limits by “personally experiencing the environment” and thus improving the efficiency of work; (5) automatic image interpretation: including the automatic determination and interpretation of radiography, micrography, and remote sensing multi-band image, synthetic aperture radar image, and space flight/space navigation image; and (6) psychological and physiological studies of human vision system and function and human brain, etc.

In addition, there are optical mice substituting the traditional roller mice, digital cameras, scanners, and fingerprint scanning recognition system, etc. Among all the products implementing the techniques of image processing (such as the abovementioned optical mouse or fingerprint scanning recognition device), an illuminating light source is a must, and the light source provided by the device itself is projected onto the scanning object and then an optical sensor is used to receive the image for further processing. Therefore, the whole digital image capturing effect substantially depends on an uniform illumination. As to the fingerprint scanner recognition device manufacturers, the way of solving the problem of non-uniformity brightness coming from both the outer sides and the middle of the lamp is the topic for research and development. Similarly, as to the optical mouse manufacturers who use an LED as the light source, the way of providing an uniform illumination is the improving objective of the manufacturers. In fact, it is easy for optical mouse users to find out that the most important part of an optical mouse resides on the digital image capturing unit. The digital image capturing unit is composed of an LED, a spotlight projecting unit, and an image sensing unit. The illumination provided by the LED is projected onto the plane in contact with the optical mouse, and the image sensing unit receives the change of image so as to converts and computes the displacement of the optical mouse. Therefore, a good and uniform illumination beam is required for an optimal detection effect. However, the common optical mouse sold in the market is unable to meet the foregoing requirements, and a darker fringe is usually formed around the bright section mainly because of the traditional LED. The package of the traditional LED puts the LED chip in the bowl section of the stand (please refer to FIGS. 3A and 3B). A conductive metal wire is connected from the anode in the middle of the LED chip to a pin of another stand. When the two power pins of the stand are connected to the DC 2.2V power supply, the LED chip starts illuminating. When the light emitted by the LED chip enters the epoxy packaging section, the index of refraction of the epoxy material is 1.4˜1.54. According to the Snell law, any light passing through two different media, a refraction and a reflection of light are produced (as shown in FIG. 4) which will cause about 40% loss of the light. In the optical path, the light passing the media of different indexes of refraction will cause a light beam in different directions and non-uniformity (as shown in FIG. 5). Further, since the anode in the middle of the LED chip is used for connecting to the power supply and does not have the illuminating function, which will cause a darker fringe problem (as shown in FIG. 6). To improve such problem, a traditional LED package has a spherical surface designed for the top of the LED package to constitute a lens effect (see FIG. 3A), so that the produced light beam can be focused at the position in the middle. However, since there are discrepancies in the design and common errors caused in the packaging process, which will cause a serious loss of light, therefore, only a small improvement can be made. Furthermore, a fringe will be produced (please see FIG. 7). Thus, in the practical application of LEDs, the light emitted by the LED chip enters the epoxy packaging material and then enters the air through the epoxy material, and is finally projected in the desired direction. The result of illumination beam is shown in FIG. 8. The middle section of the light beam is brighter than the area connecting to the middle of the light beam and its periphery, which will cause a darker fringe and distort the gray scale value of the image captured by the optical mouse. The image sensing processor cannot accurately compute the distance and direction of the mouse's displacement, more particularly when the desktop is smooth. It is perceived that the light focusing effect of an uniform illumination beam still needs improvements.

The U.S. Pat. No. 6,476,970B1 entitled “Illumination Optics and Method” disclosed by Smith on Aug. 10, 2000 as shown in FIGS. 9, 10, and 11 can eliminate the abovementioned darker fringes, but the final result only gives an uniform illuminated light beam of about 1 mm×1 mm. The method taught by Smith uses a Fresnel lens to receive the light emitted from the LED, and collimate the light beam of about 1 mm×1 mm at the illuminating light beam of about 6 mm×6 mm, but it still produces a dark region. A prism with several refractive facets is used to divide the collimating light beam into 9 blocks. These 9 blocks of splitting beams are overlapped to form a light beam again. The area of about 1 mm×1 mm in the middle is a very bright and uniform illumination beam (as shown in FIG. 11). Such method requires integrating a prism and a plurality of refractive facets into an optical component (see FIGS. 9 and 10). Plastic Materials are adopted in the optical process for lowering the production cost, but the mold preparation must be very precise, not only bearing a very high molding cost, but also having technical difficulties of effectively controlling the yield rate of the product due to the contraction and deformation problems occurred in the cooling process of the plastic mold injection. Therefore, such method cannot be used for mass production in order to lower the production cost effectively.

From the description above, it is obvious that traditional LED structures usually produce fringes and cause the image captured by the optical mice to distort in its gray scale value. The image sensing processor cannot compute the distance and direction of the mouse's displacement accurately, and cannot improve the sensitivity of the mouse. As to the technology disclosed in the U.S. Pat. No. 6,476,970, although it can effectively overcome the shortcomings of the fringes produced by the LED structure, it also brings in a complicated structure which will increase the cost and make the mass production difficult. Such technology requires further improvements.

In view of the foregoing shortcomings of the prior arts, the inventor of this invention conducted extensive researches and experiments and applied related theories to finally invent the present invention. This invention can effectively solve the problem, and make the light illumination beam emitted by the LED to travel in the same direction and also achieve the uniform and highly efficient focusing functions. Therefore, the optical mouse adopting the LED package structure of this invention can compute the distance and direction of the mouse's displacement more accurately in order to improve the operational sensitivity of the mouse.

### SUMMARY OF THE INVENTION

The primary object of the invention is to provide an improved LED package, which comprises a stand, an LED chip, and an epoxy packaging object, wherein a bowl section for accommodating the LED chip is disposed on the stand, and the present invention improves the prior-art LED package to allow the illuminating light emitted from the LED to travel in the same direction, and thus achieving the uniform and highly efficient light focusing function. As a result, the optical mouse can capture an image with a better gray scale contrast effect, and let the image sensing processor compute the distance and direction of the mouse's displacement more accurately.

Another object of the present invention is to provide an improved LED package, wherein the bowl section for accommodating the LED chip is in an elliptic shape. Comparing to the traditional design with aslant surfaces, the present invention can have a better light focusing effect.

Yet, another object of the present invention is to provide an improved LED package, wherein the improved epoxy package not only has a simple, easy-to-manufacture structure which almost increase no manufacturing cost, and has a price advantage over the prior art as disclosed in the U.S. Pat. No. 6,476,970.

### BRIEF DESCRIPTION OF THE DRAWINGS

FIG. 1 is an illustrative diagram showing the theory of digital image processing.

FIG. 2 is an illustrative diagram of sampling the grid of a digital image.

FIG. 3 is an illustrative diagram of a conventional LED package.

FIG. 4 is an illustrative diagram of the refractive and reflective paths produced when the light from the LED passes through different media according to prior arts.

FIG. 5 is an illustrative of the polarity of the light emitted from the LED according to prior arts.

FIG. 6 is an illustrative diagram of the darker area in the middle of the LED chip.

FIG. 7 is an illustrative diagram of a fringe.

FIG. 8 is an illustrative diagram showing the problem of darker fringes.

FIG. 9 is an illustrative diagram of the optical path as disclosed in the U.S. Pat. No. 6,476,970B1.

FIG. 10 is a perspective diagram of the plurality of refractive facets as disclosed in the U.S. Pat. No. 6,476,970B1.

FIG. 11 is an illustrative diagram of the functional process as disclosed in the U.S. Pat. No. 6,476,970B1.

FIG. 12 is an illustrative diagram of the LED package according to the present invention.

FIG. 13 is an illustrative diagram of another preferred embodiment of the present invention.

FIG. 14 is an illustrative diagram of the polarity of the light emitted from the LED according to the present invention.

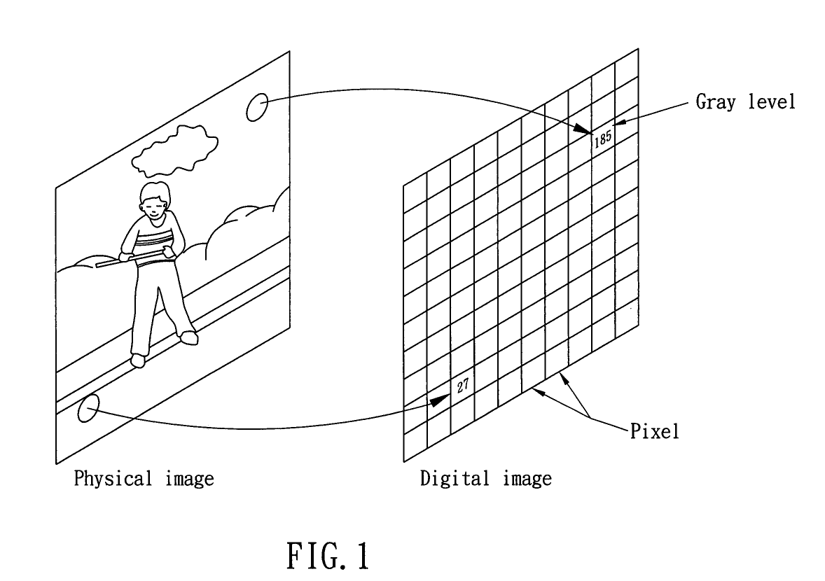

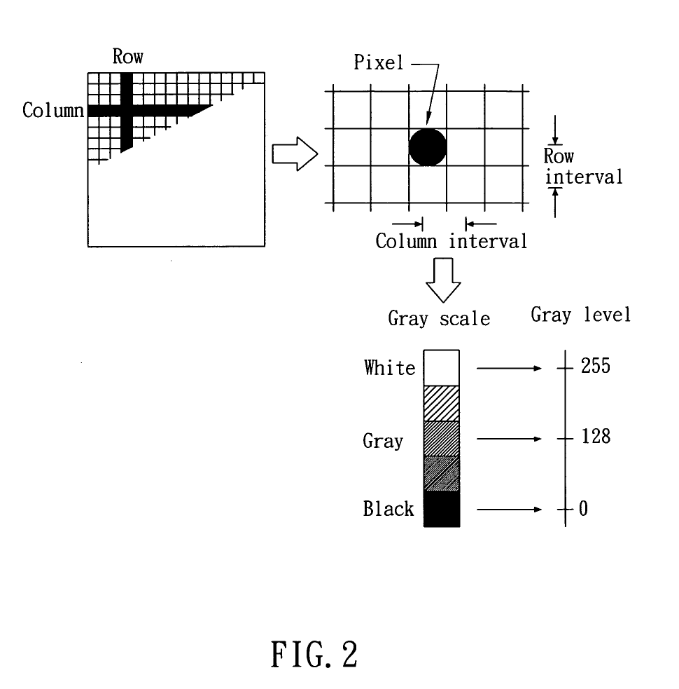

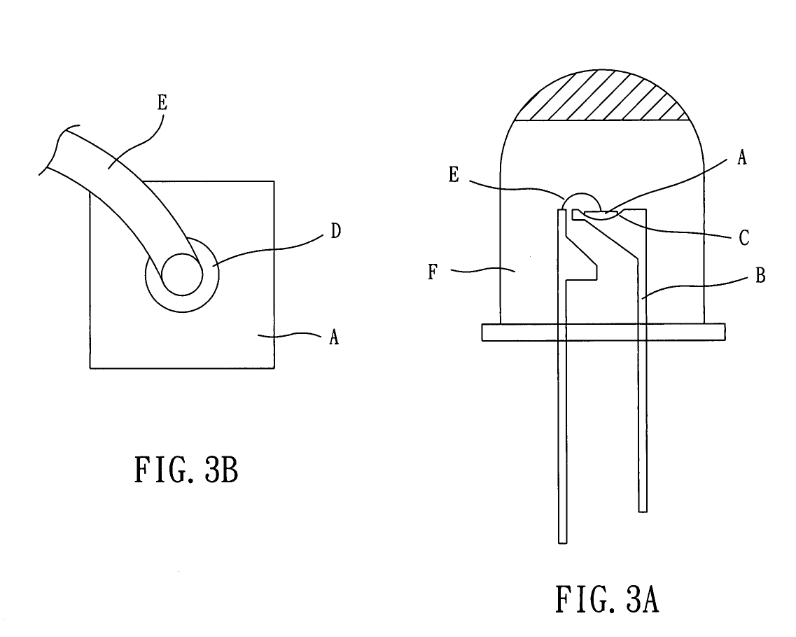

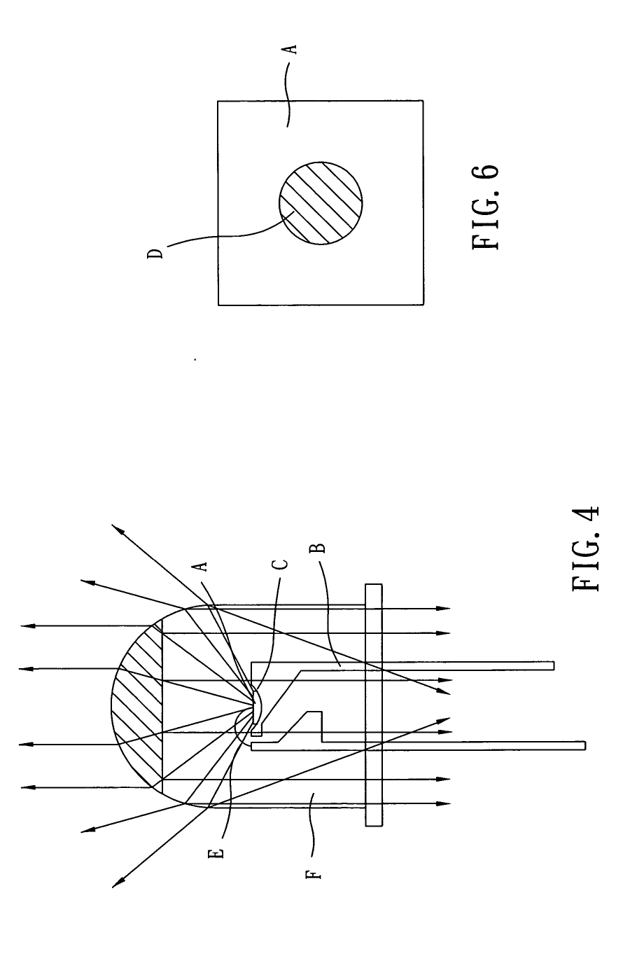

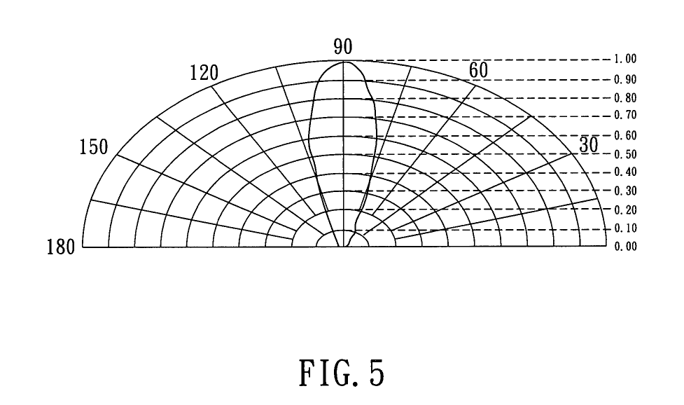

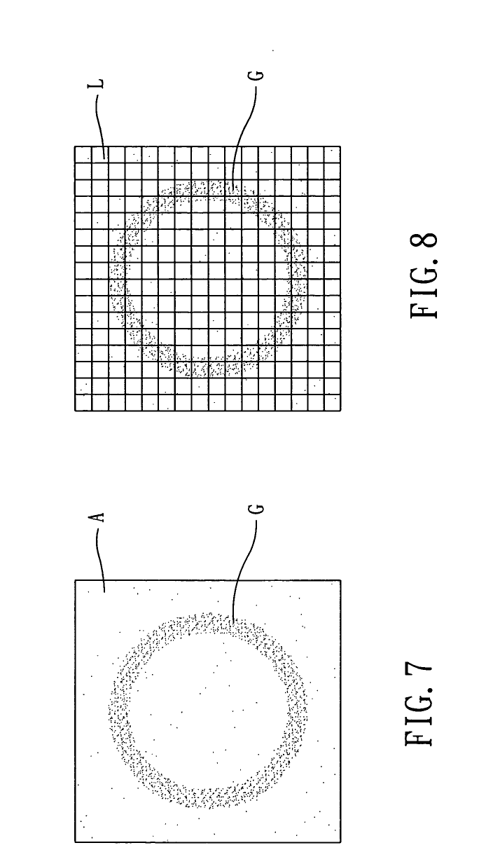

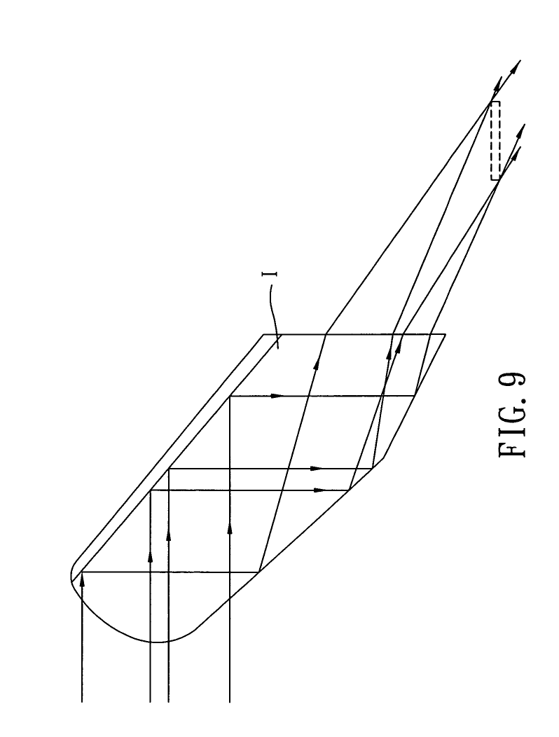

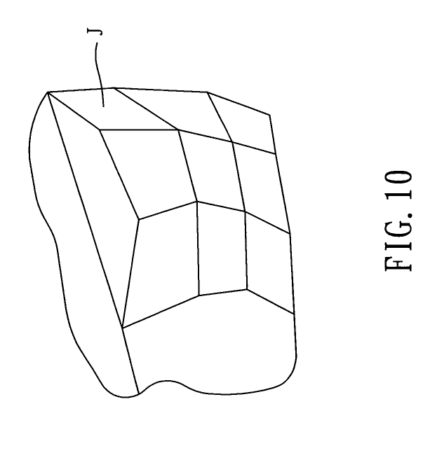

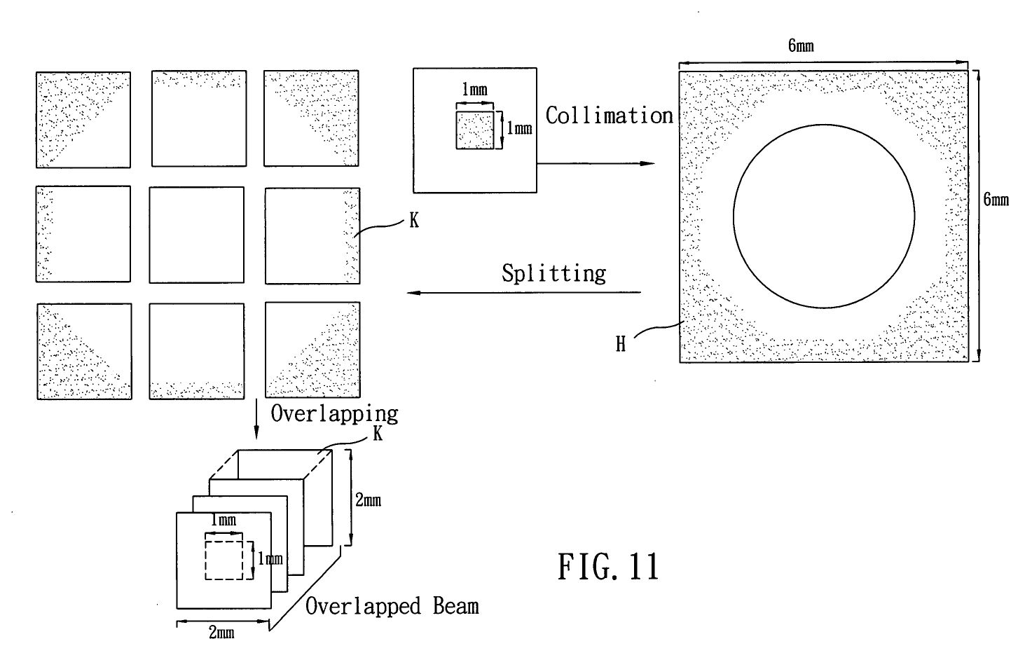

### DESCRIPTION OF THE PREFERRED EMBODIMENT

The objects, spirits and advantages of the preferred embodiments of the present invention will be readily understood by the accompanying drawings and detailed descriptions, wherein:

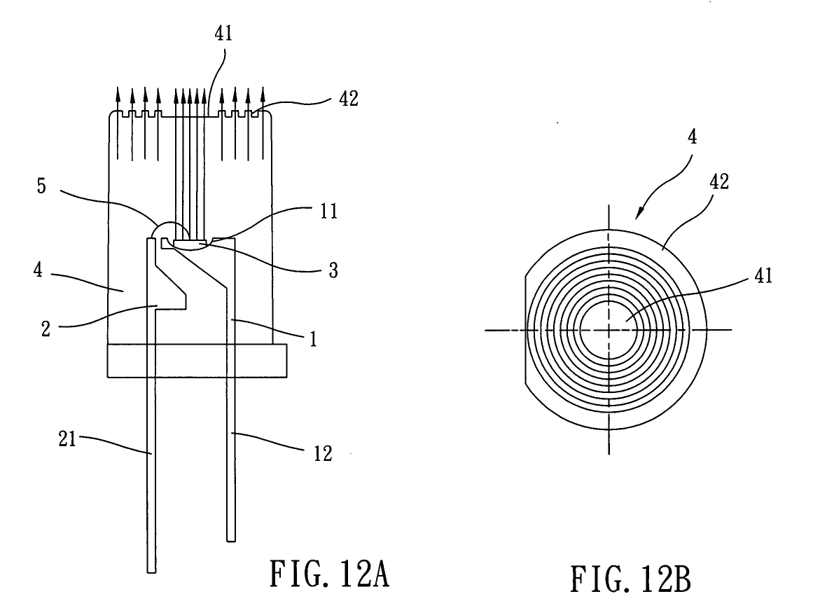

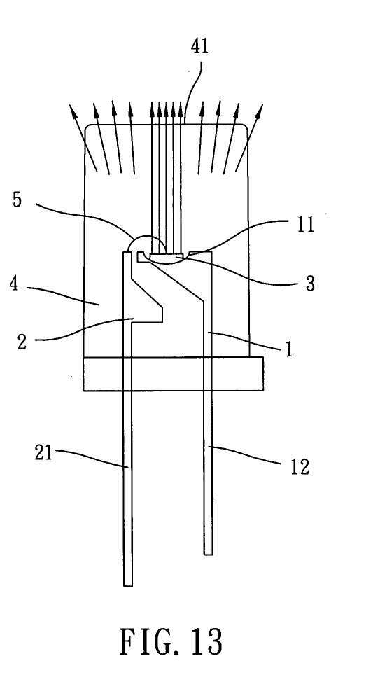

Please refer to FIGS. 12A and 12B for the front view and top view of the present invention respectively. The improved LED package disclosed in this invention comprises a first stand 1, a second stand 2, an LED chip 3, and an epoxy packaging object 4, wherein the first stand 1 has a concave bowl section 11; a pin 12 is extended from the bottom of the bowl section 11; the second stand 2 is disposed adjacent to the first stand 1 but keeps a certain distance from the first stand 1; a second pin 21 is disposed at the bottom of the second stand 2; the LED chip is disposed in the bowl section 11 at the top of the first stand 1; the anode of the LED chip 3 uses a conductive metal wire 5 is electrically connected to the second stand 5; the epoxy packaging object 4 contains the foregoing first stand 1, second stand 2, LED chip 3, and leaves the first pin 12 and the second pin 21 exposed from the epoxy packaging object 4; a plane 41 vertical to the traveling direction of the light emitted from the LED chip 3 is disposed on the top surface of the epoxy packaging object 4; and more than one circular protrusion 42 is disposed on such top surface.

The present invention has the foregoing design primarily because the result of many experiments conducted by the inventor shows that the brightness of the light projecting direction can be improved by 25% if the included angle of the light projection is designed as 90 degrees with respect to the light emitted from the LED chip in the horizontal direction (please see FIG. 13). Therefore, the flat-top package of the LED can improve the angle of the projecting light to give a high-intensity and uniform illuminating light beam. This is the breakthrough discovered by the inventor of this invention. However, only a flat-top packaging structure cannot fully solve the problem of the darker fringes, thus the inventor further conducted research and development and applied related theories for the experiment, and finally invented a new LED package.

The LED package and design according to the present invention has a flat top structure with a plurality of protrusions (as shown in FIGS. 12A and 12B) characterized in that a single flat top LED package is changed into a plurality of flat-top LEDs, not only increasing the area and quantity of the refractive facets and the magnitude of the light refraction, but also greatly reducing the loss of light at the same time.

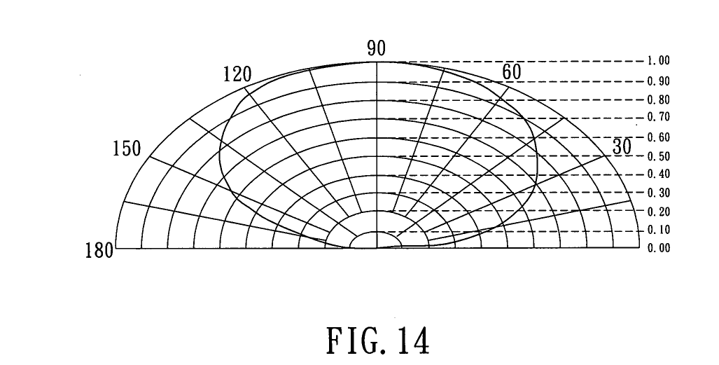

Since the light emitted from a plurality of flat-top LEDs is refracted and projected, the brightness can be improved, and the illuminating light beam also can have a better uniformity. As a result, an illuminating light beam with a light focusing range of about 150 degrees (as shown in FIG. 14) and an uniform area of about 3 mm×3 mm which is much larger than the even area of 1 mm×1 mm of the illuminating light obtained by the Smith's method.

In view of the description above, this invention has the following advantages over the prior-art structure and other technologies:
1. The present invention provides a larger area of bright and uniform illuminating light beams.
2. The present invention provides an effective light focusing range of about 150 degrees which is much higher than that of the traditional LED package.
3. The present invention can completely eliminate the darker fringes, so that the optical mouse can capture an image with a better gray scale contrast effect, and allow the image sensing processor to compute the distance and direction of the mouse's displacement more accurately
4. The mold design of the LED package is simple, which is superior to the complicated optical structure disclosed by Smith and can give a higher yield for the mass production.
5. Since the magnitude of light refraction is increased, the loss of reflected light is also reduced greatly at the same time. Therefore, an LED chip with a low brightness can be used to achieve the illuminating light beam with the same required brightness and uniformity. Such arrangement can lower the LED production cost.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

In summary that this invention has been disclosed and illustrated with reference to particular embodiments, the principles involved are susceptible for use in numerous other embodiments that will be apparent to persons skilled in the art. Consequently, the present invention has been examined to be progressive and has great potential in commercial applications.

1. An improved LED package, comprising:
a first stand, having a concave bowl section thereon and a first pin extended from the bottom thereof;
a second stand, being adjacent to but a distance apart from said first stand, and having a second pin disposed at the bottom of said second stand;
an LED chip, being disposed in said bowl section, and using a conductive metal wire to electrically couple to said second stand; and
a packaging object, for encapsulating said first stand, second stand, and LED chip, and exposing only said first pin and second pin, and having a plane perpendicular to the light traveling direction and disposed at a top surface of said packaging object, and said top surface comprising at least a circular protrusion.

2. The improved LED package of claim 1, wherein said first bowl section disposed on said first stand has an elliptic cross section.

3. The improved LED package of claim 1, wherein said conductive metal wire has one end coupled to the anode of said LED chip.

4. The improved LED package of claim 1, wherein said packaging object is epoxy.
